(19) United States
(12) Patent Application Publication
(10) Pub. No.: US 2014/0061920 A1
(43) Pub. Date: Mar. 6, 2014

(54) SEMICONDUCTOR DEVICE

(71) Applicant: PANASONIC CORPORATION, Osaka (JP)

(72) Inventors: Hiroshige HIRANO, Niigata (JP); Yutaka ITOH, Toyama (JP); Hiroyuki ISHIDA, Toyama (JP); Kazuhiro ISHIKAWA, Toyama (JP)

(73) Assignee: PANASONIC CORPORATION, Osaka (JP)

(21) Appl. No.: 14/078,022

(22) Filed: Nov. 12, 2013

Related U.S. Application Data
(63) Continuation of application No. PCT/JP2012/003733, filed on Jun. 7, 2012.

(30) Foreign Application Priority Data
Jun. 24, 2011 (JP) 2011-140401

(51) Int. Cl. H01L 23/532

(52) U.S. Cl. CPC H01L 23/53238
USPC 257/751

(57) ABSTRACT

A semiconductor device includes: a first insulating film formed on a semiconductor substrate; a first interconnect formed on the first insulating film; a second insulating film formed on the first insulating film to cover the first interconnect; and a second interconnect formed on the second insulating film. The second interconnect includes a barrier layer formed on the second insulating film, and a plated layer formed on the barrier layer. The barrier layer prevents diffusion of atoms forming the plated layer into the second insulating film, and has a greater width than the plated layer.

### CROSS-REFERENCE TO RELATED APPLICATIONS

This is a continuation of International Application No. PCT/JP2012/003733 filed on Jun. 7, 2012, which claims priority to Japanese Patent Application No. 2011-140401 filed on Jun. 24, 2011. The entire disclosures of these applications are incorporated by reference herein.

### BACKGROUND

The present disclosure relates to semiconductor devices and methods for fabricating the same, and more particularly relates to a semiconductor device including a redistribution layer formed on a semiconductor chip, and a method for fabricating the same.

Processes for forming a relatively thick interconnect, for example, on a semiconductor substrate or in a semiconductor device include a semi-additive process. For example, Japanese Unexamined Patent Publication No. 2006-24902 describes a method in which an interconnect is formed on an insulative substrate by the semi-additive process.

FIGS. 20A-20D schematically illustrate the interconnect formation method described in Japanese Unexamined Patent Publication No. 2006-24902. It is assumed that, for example, an interconnect pattern here include 10-μm-or-more-thick lines and spaces both having a width of 10 μm or less.

First, as illustrated in FIG. 20A, an electroless copper-plated layer 52 is formed on a surface of a substrate 51 made of an insulative resin. Subsequently, resist patterns 57a are formed on a surface of the electroless copper-plated layer 52 to expose regions of the electroless copper-plated layer 52 on which interconnect traces are to be formed.

Next, as illustrated in FIG. 20B, etching barrier plated layers 54 made of a metal different from copper are formed on the regions of the electroless copper-plated layer 52 exposed from the resist patterns 57a. Subsequently, electro copper-plated layers 53 forming portions of interconnect traces 59 are each formed on a surface of a corresponding one of the etching barrier plated layers 54.

Next, as illustrated in FIG. 20C, the resist patterns 57a are removed, and then, as illustrated in FIG. 20D, portions of the electroless copper-plated layer 52 exposed on the surface of the substrate 51 are removed by etching.

In the conventional interconnect formation method in which the interconnect traces 59 are formed on the substrate 51 made of the resin as above, when the portions of the electroless copper-plated layer 52 formed on the substrate 51, which serve as seed layers, recesses are formed in lateral end portions of each of portions of the electroless copper-plated layer 52 under the electro copper-plated layers 53. In other words, etching of the portions of the electroless copper-plated layer 52 proceeds in lateral directions. The reason for this is that the electroless copper-plated layer 52 does not have good adhesion to the substrate 51.

Such recesses make it difficult to reduce the width of each of the interconnect traces 59, and the etching barrier plated layers 54 made of a metal except copper are, therefore, formed on the electroless copper-plated layer 52 to improve adhesion between the interconnect traces 59 and the substrate 51.

### SUMMARY

When the interconnect formation method according to the conventional example is utilized as a method for forming redistribution interconnects for an integrated circuit (a semiconductor chip), the application of a strong electric field between each of redistribution interconnects (external interconnects) and a lower interconnect (an internal interconnect) below the redistribution interconnect induces a leakage current therebetween. This results from the phenomenon where, for example, when the redistribution interconnects contain copper as the main ingredient, copper atoms forming the redistribution interconnects diffuse into an interlayer insulating film configured to insulate the redistribution interconnects from the lower interconnects. For example, even when a barrier layer made of silicon nitride (SiN) serving as a barrier against copper atoms is formed below the redistribution interconnects, the application of a strong electric field between the interconnects causes diffusion of copper atoms, resulting in a leakage current therebetween.

The present disclosure was made to solve the problem, and it is an object of the present disclosure to prevent a leakage current between a lower interconnect (e.g., an interconnect made of a thin film in an integrated circuit) and an upper interconnect (e.g., a redistribution interconnect made of a thick film).

In order to achieve the object, a semiconductor device of the present disclosure includes a barrier layer provided between a first interconnect (a lower interconnect) and a second interconnect (a redistribution interconnect) and having a greater width than the second interconnect.

Specifically, a semiconductor device according to the present disclosure includes: a first insulating film formed on a semiconductor substrate; a first interconnect formed on the first insulating film; a second insulating film formed on the first insulating film to cover the first interconnect; and a second interconnect formed on the second insulating film. The second interconnect includes a first barrier layer formed on the second insulating film, and a first conductive layer formed above the first barrier layer, the first barrier layer prevents atoms forming the first conductive layer from diffusing into the second insulating film, and a width of the first barrier layer is greater than a width of the first conductive layer.

According to the semiconductor device of the present disclosure, the first barrier layer prevents diffusion of atoms forming the first conductive layer into the second insulating film, and has a greater width than the first conductive layer. This enhances the effect of preventing the atoms forming the first conductive layer from diffusing into the first interconnect. Specifically, the first barrier layer is provided between the first conductive layer and the first interconnect to reliably cross the direction of application of an electric field. This can prevent the first conductive layer from being shorted to the first interconnect.

In the semiconductor device of the present disclosure, the second interconnect may further include a seed layer formed between the first barrier layer and the first conductive layer.

Thus, when plating is used to form the first conductive layer, the provision of the low-resistance seed layer allows the first conductive layer to be efficiently formed by electroplating.

The semiconductor device of the present disclosure may further include a protective film formed on an upper surface or a side surface of the second interconnect.

Thus, when the protective film is an insulating film, foreign matter, for example, can be prevented from causing current leakage between the first conductive layer and an adjacent first conductive layer. Also when the protective film is a barrier film against a material of the first conductive layer, the diffusion of the material can be similarly prevented from causing the current leakage between the first conductive layer and an adjacent first conductive layer.

In this case, the protective film may be formed on the side surface of the second interconnect, and the protective film may be formed without covering a side surface of the first barrier layer.

This can ensure that the first barrier layer has a greater width than the first conductive layer. Furthermore, the first barrier layer and the first conductive layer can be formed through a single patterning process step, thereby simplifying a fabrication process. Moreover, since the thickness of the protective film determines the width of the second interconnect, this helps reduce the distance between each adjacent pair of second interconnects. In addition, since the protective film is formed on the side surface of the second interconnect, this can prevent adjacent two of the second interconnects from being shorted to each other.

In the semiconductor device of the present disclosure, the second interconnect may further include a second barrier layer formed below the first barrier layer.

Thus, if the seed layer formed to grow, for example, the first conductive layer by plating is replaced with the second barrier layer, the second barrier layer is not etched during the removal of the seed layer, and the shape of the second barrier layer can be maintained. Thus, a combination of the first barrier layer and the second barrier layer is useful as a barrier layer that is a component of the second interconnect.

In the semiconductor device of the present disclosure, the second interconnect may further include a second conductive layer formed on the first conductive layer and including at least one layer.

As such, a material functioning to prevent oxidation of the first conductive layer and prevent diffusion of a material of the first conductive layer is selected as a material of the second conductive layer to ensure the stability of a portion of the first conductive layer connected to outside the semiconductor device (e.g., a wire-bonded portion thereof). For example, when the second conductive layer is a stack of nickel (Ni) and gold (Au), nickel prevents diffusion of copper forming the first conductive layer, and gold has advantages, such as the advantage of preventing oxidation.

In this case, in the second interconnect, the width of the second conductive layer may be greater than the width of the first barrier layer.

Thus, the first barrier layer, the first conductive layer, and the second conductive layer can be formed through a single patterning process step, thereby simplifying a fabrication process.

In this case, the semiconductor device of the present disclosure may further include a protective film formed on a side surface of the second interconnect. In the second interconnect, the width of the first barrier layer may be greater than a width of the second conductive layer, and the width of the second conductive layer may be greater than the width of the first conductive layer.

Thus, for example, the first barrier layer is formed using a mask different from a mask pattern used to form the first conductive layer, thereby allowing the first barrier layer to have a sufficiently large thickness. This ensures that electrodiffusion of a material of the first conductive layer into the first interconnect is reduced. Among fabrication processes, a process in which the first barrier layer is patterned before the formation of the second interconnect eliminates the need for patterning a deep portion of the first barrier layer. A process in which the first barrier layer is patterned after the formation of the second interconnect allows the first barrier layer and the seed layer forming a portion of the second interconnect to be formed through successive process steps, and thus, eliminates the need for, for example, cleaning the layers after the formation of each of the layers. Furthermore, after the formation of the first conductive layer, the protective film can be formed, and the formed protective film can be patterned. Then, the first barrier layer can be patterned using the patterned protective film as a mask. Such a process allows the patterning of a portion of the formed protective film immediately above the second interconnect at the same time as the patterning of the first barrier layer.

In this case, the protective film may cover a side surface of the first barrier layer.

Thus, a portion of the protective film above the first barrier layer is not patterned, and the protective film, therefore, covers an entire upper surface of a semiconductor device. This can provide a semiconductor device with higher reliability.

In the semiconductor device of the present disclosure, the first conductive layer of the second interconnect may be made of a material containing copper.

Thus, the material containing copper can reduce the resistance of the second interconnect.

A method for fabricating a semiconductor device according to the present disclosure includes: forming a first insulating film on a semiconductor substrate; selectively forming a first interconnect on the first insulating film; forming a second insulating film on the first insulating film to cover the first interconnect; and forming a second interconnect on the second insulating film. The forming of the second interconnect includes forming a barrier layer on the second insulating film, and forming a conductive layer above the barrier layer, the barrier layer prevents atoms forming the conductive layer from diffusing into the second insulating film, and a width of the barrier layer is greater than a width of the conductive layer.

According to the method of the present disclosure, the barrier layer prevents diffusion of atoms forming the conductive layer into the second insulating film, and has a greater width than the conductive layer. This enhances the effect of preventing the atoms forming the conductive layer from diffusing into the first interconnect. Specifically, the barrier layer is provided between the conductive layer and the first interconnect to reliably cross the direction of application of an electric field. This can prevent the conductive layer from being shorted to the first interconnect.

In the method of the present disclosure, the forming of the second interconnect may include: selectively forming a conductive layer above the barrier layer; patterning the barrier layer using the selectively formed conductive layer as a mask; and after the patterning of the barrier layer, etching both side portions of the conductive layer.

As such, the barrier layer is patterned using the conductive layer as a mask, and then, both the side portions of the conductive layer are etched. This can ensure that the barrier layer has a greater width than the conductive layer.

In this case, in the selective forming of the conductive layer and the patterning of the barrier layer, wet etching is preferably used.

In the method of the present disclosure, the forming of the second interconnect may include: selectively forming a conductive layer above the barrier layer; selectively forming protective films on both side surfaces of the selectively formed conductive layer; and patterning the barrier layer using the conductive layer on which the protective films have been formed as a mask.

As such, the protective films are selectively formed on both side surfaces of the conductive layer, and the barrier layer is patterned using the conductive layer on which the protective films have been formed as a mask. This can ensure that the barrier layer has a greater width than the conductive layer.

In the method of the present disclosure, the conductive layer of the second interconnect may be made of a material containing copper.

Thus, the material containing copper can reduce the resistance of the second interconnect.

According to the semiconductor device of the present disclosure and the method for fabricating the same, the leakage current between a lower interconnect and an upper interconnect can be prevented, thereby preventing the lower interconnect from being shorted to the upper interconnect.

### BRIEF DESCRIPTION OF THE DRAWINGS

FIG. 1 illustrates a principal portion of a semiconductor device according to a first embodiment of the present disclosure, and is a cross-sectional view taken along the line I-I in FIG. 2.

FIG. 2 is a plan view schematically illustrating the principal portion of the semiconductor device according to the first embodiment of the present disclosure.

FIGS. 3A-3D are cross-sectional views sequentially illustrating process steps in a method for fabricating a semiconductor device according to the first embodiment of the present disclosure.

FIGS. 4A-4C are cross-sectional views sequentially illustrating other process steps in the method for fabricating a semiconductor device according to the first embodiment of the present disclosure.

FIG. 5 illustrates a principal portion of a semiconductor device according to a second embodiment of the present disclosure, and is a cross-sectional view taken along the line V-V in FIG. 6.

FIG. 6 is a plan view schematically illustrating the principal portion of the semiconductor device according to the second embodiment of the present disclosure.

FIGS. 7A-7C are cross-sectional views sequentially illustrating process steps in a method for fabricating a semiconductor device according to the second embodiment of the present disclosure.

FIG. 8 illustrates a principal portion of a semiconductor device according to a third embodiment of the present disclosure, and is a cross-sectional view taken along the line VIII-VIII in FIG. 9.

FIG. 9 is a plan view schematically illustrating the principal portion of the semiconductor device according to the third embodiment of the present disclosure.

FIGS. 10A-10D are cross-sectional views sequentially illustrating process steps in a first method for fabricating a semiconductor device according to the third embodiment of the present disclosure.

FIGS. 11A-11E are cross-sectional views sequentially illustrating process steps in a second method for fabricating a semiconductor device according to the third embodiment of the present disclosure.

FIG. 12 illustrates a principal portion of a semiconductor device according to a fourth embodiment of the present disclosure, and is a cross-sectional view taken along the line XII-XII in FIG. 13.

FIG. 13 is a plan view schematically illustrating the principal portion of the semiconductor device according to the fourth embodiment of the present disclosure.

FIGS. 14A-14D are cross-sectional views sequentially illustrating process steps in a first method for fabricating a semiconductor device according to the fourth embodiment of the present disclosure.

FIGS. 15A-15E are cross-sectional views sequentially illustrating process steps in a second method for fabricating a semiconductor device according to the fourth embodiment of the present disclosure.

FIG. 16 illustrates a principal portion of a semiconductor device according to a fifth embodiment of the present disclosure, and is a cross-sectional view taken along the line XVI-XVI in FIG. 17.

FIG. 17 is a plan view schematically illustrating the principal portion of the semiconductor device according to the fifth embodiment of the present disclosure.

FIGS. 18A-18D are cross-sectional views sequentially illustrating process steps in a first method for fabricating a semiconductor device according to the fifth embodiment of the present disclosure.

FIGS. 19A-19C are cross-sectional views sequentially illustrating process steps in a second method for fabricating a semiconductor device according to the fifth embodiment of the present disclosure.

FIGS. 20A-20D are cross-sectional views sequentially illustrating process steps in a conventional interconnect formation method.

### DETAILED DESCRIPTION

### First Embodiment

A semiconductor device according to a first embodiment of the present disclosure will be described with reference to the drawings.

A feature of a semiconductor device according to the present disclosure is that the semiconductor device prevents copper, which is a main ingredient of an interconnect, from diffusing into a lower interconnect formed with an insulating film of, e.g., silicon nitride (SiN) interposed between the interconnect and the lower interconnect, and thus, prevents the interconnect from being shorted to the lower interconnect. Specifically, the width of, e.g., a titanium (Ti) film that is a barrier film configured to prevent diffusion of copper is greater than that of the interconnect containing copper as the main ingredient to ensure that copper is prevented from diffusing into the lower interconnect.

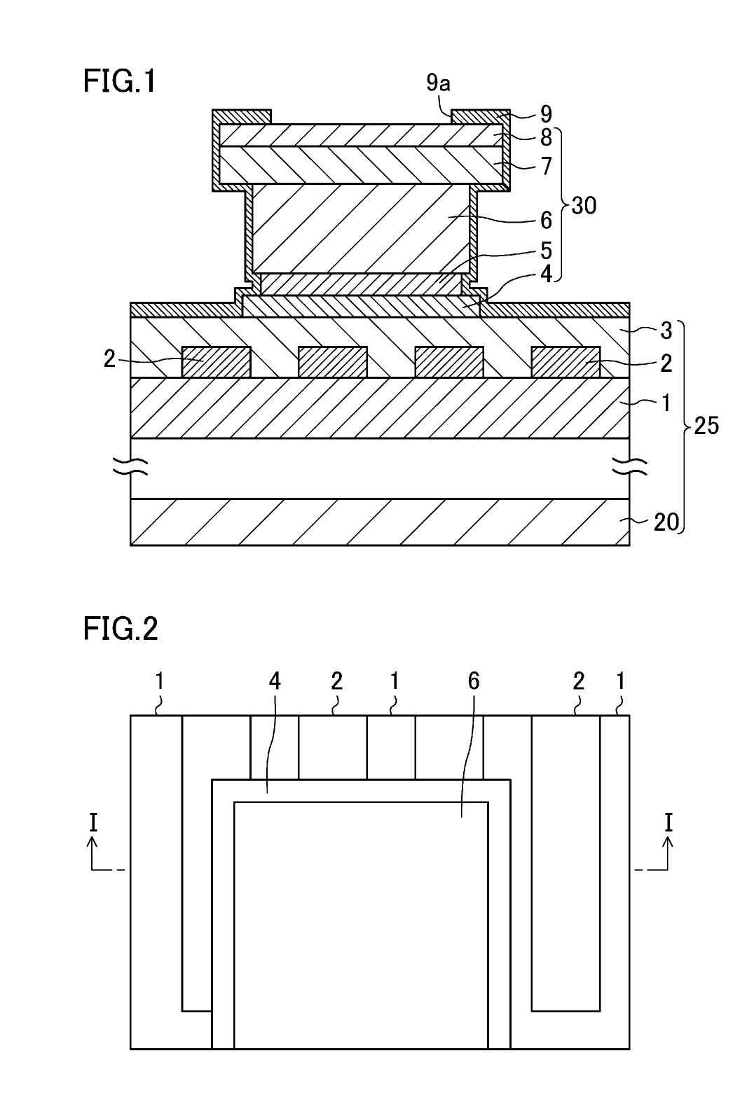

More specifically, as illustrated in FIGS. 1 and 2, a plurality of second interconnects 30 that are redistribution interconnects are formed on a semiconductor chip 25 including a plurality of first interconnects 2 that are internal interconnects. Although only one of the second interconnects 30 is illustrated here, the second interconnects 30 are formed on the semiconductor chip 25.

The semiconductor chip 25 includes an unshown active element, an unshown passive element, and a plurality of unshown interconnect layers formed on a semiconductor substrate 20 made of, e.g., silicon (Si). The first interconnects 2 form uppermost interconnect layers among the interconnect layers made of, e.g., aluminum (Al), and are selectively formed on a first insulating film 1 made of, e.g., silicon dioxide (SiO₂). Instead of Al, copper (Cu) can be used as a material of the first interconnects 2. A second insulating film 3 is formed on the first insulating film 1 to cover the first interconnects 2, and is a single-layer film made of, e.g., silicon nitride (SiN), or a multilayer film made of TEOS (tetra-ethyl-ortho-silicate) and SiN.

The second interconnects 30 formed on the second insulating film 3 each include a barrier layer 4 made of, e.g., titanium (Ti) and serving as a barrier against diffusion of copper (Cu), a seed layer 5 made of Cu, a plated layer 6 made of Cu or an alloy containing Cu as the main ingredient, a nickel (Ni) layer 7 configured to prevent diffusion of Cu and increase the hardness of the second interconnect 30, and a gold (Au) layer 8 having good resistance to oxidation and improving the electrical and mechanical connectivity between the second interconnect 30 and a wire bonded to the second interconnect 30 or solder. The barrier layer 4, the seed layer 5, the plated layer 6, the Ni layer 7, and the Au layer 8 are formed sequentially from bottom to top.

As seen from FIGS. 1 and 2, the barrier layer 4 made of Ti forms a portion of the second interconnect 30, and has a larger area when viewed from above than the plated layer 6 made of Cu. This enhances the effect of preventing Cu atoms of the plated layer 6 from diffusing into the first interconnects 2. Specifically, since the barrier layer 4 is provided between the plated layer 6 and the first interconnects 2 to cross the direction of application of an electric field, this provision can prevent the plated layer 6 from being shorted to the first interconnects 2.

While the second interconnect 30 may be electrically connected to the first interconnects 2, it does not need to be connected to the first interconnects 2.

A protective film (passivation film) 9 made of, e.g., silicon nitride (SiN) is formed on the second insulating film 3 to cover upper and side surfaces of the second interconnect 30. The protective film 9 may have an opening 9a through which the second interconnect 30 is electrically connected to outside the semiconductor device. Although not shown, pad electrodes may be formed on regions of the second insulating film 3 immediately above the first interconnects 2 so as to be connected directly to the first interconnects 2. The width of each of the regions of the second insulating film 3 on which the pad electrodes are formed is about 100 μm.

In FIG. 2, the second insulating film 3, the Ni layer 7, the Au layer 8, and the protective film 9 are omitted.

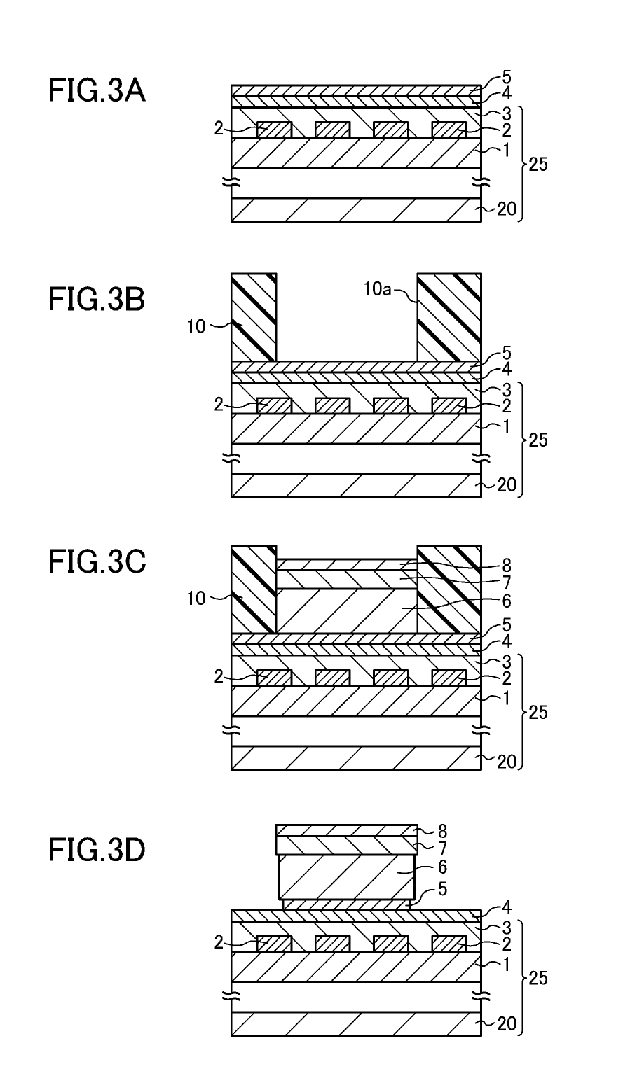

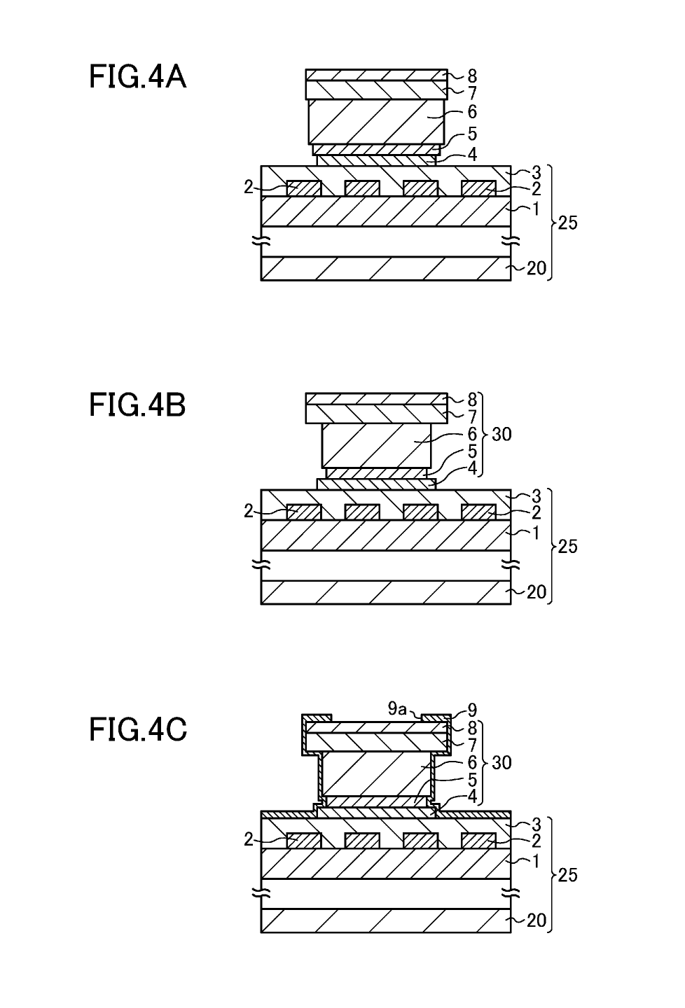

A method for fabricating the semiconductor device configured as above will be described hereinafter with reference to FIGS. 3A-4C.

First, as illustrated in FIG. 3A, a first insulating film 1 made of, e.g., SiO₂ is formed, by, for example, chemical vapor deposition (CVD), on a semiconductor substrate 20 on which an active element, interconnect layers, and other elements are formed. Subsequently, an interconnect formation film made of, e.g., aluminum (Al) is deposited on the first insulating film 1 by sputtering. Thereafter, the interconnect formation film is patterned as desired by lithography and etching, thereby forming a plurality of first interconnects 2. Subsequently, a second insulating film 3 made of SiN is deposited on the first insulating film 1 by CVD to cover the first interconnects 2. When the second insulating film 3 is a multilayer film including a TEOS film formed by spin coating and a SiN film deposited by CVD, this allows easier filling of the gap between each adjacent pair of the first interconnects 2. Then, an upper surface of the deposited second insulating film 3 is planarized by chemical mechanical polishing (CMP). The upper surface of the second insulating film 3 does not always need to be planarized. Subsequently, a barrier layer 4 made of, e.g., Ti is deposited on the second insulating film 3 by sputtering, and a seed layer 5 made of Cu is deposited on the barrier layer 4 by sputtering.

Next, as illustrated in FIG. 3B, a resist film 10 is formed on the seed layer 5 by lithography, and has an opening pattern 10a on a region of the seed layer 5 on which a second interconnect is to be formed.

Next, as illustrated in FIG. 3C, a plated layer 6 made of Cu is grown on the seed layer 5 by electroplating using the resist film 10 as a mask. Subsequently, a Ni layer 7 and an Au layer 8 are sequentially grown on the plated layer 6 by electroplating.

Next, as illustrated in FIG. 3D, the resist film 10 is removed, and then, the seed layer 5 is etched by wet etching using, e.g., a mixture of sulfuric acid and a hydrogen peroxide solution as an etchant. The mixture can etch only copper (Cu), and, in other words, has a high etch rate for Cu. Here, the thickness of the seed layer 5 made of Cu is about 0.2 μm. The thickness of the plated layer 6 similarly made of Cu is about 3-10 μm. Furthermore, since the seed layer 5 is formed by sputtering, the density of the seed layer 5 is lower than that of the plated layer 6. Thus, the etch rate of the seed layer 5 is lower than that of the plated layer 6, and the seed layer 5 can be, therefore, selectively etched using the plated layer 6 as a mask. This etching is wet etching, and therefore, recesses are each formed in a side surface of the seed layer 5 by isotropic etching. In other words, the etching of the seed layer 5 proceeds in lateral directions. The recesses each have a depth of about 0.2 μm from a corresponding one of side surfaces of the plated layer 6, i.e., a depth substantially equal to the thickness of the seed layer 5.

Next, as illustrated in FIG. 4A, the barrier layer 4 is etched by wet etching using, e.g., hydrofluoric acid as an etchant. Hydrofluoric acid can etch only titanium (Ti), and, in other words, has a high etch rate for Ti. Also here, the thickness of the barrier layer 4 made of Ti is about 0.2 μm, and recesses are, therefore, each formed in a side surface of the barrier layer 4. In other words, the etching of the barrier layer 4 proceeds in lateral directions. The recesses each have a depth of about 0.2 μm from a corresponding one of side surfaces of the seed layer 5, i.e., a depth substantially equal to the thickness of the barrier layer 4. In such a state, the area of the barrier layer 4 when viewed from above is smaller than that of the seed layer 5 when viewed from above or that of the plated layer 6 when viewed from above. Specifically, the barrier layer 4 does not block a path through which Cu diffuses. To address this problem, in this embodiment, the seed layer 5 and the plated layer 6 are again etched by wet etching such that the width of each of the seed layer 5 and the plated layer 6 both made of Cu (the area of each of the seed layer 5 and the plated layer 6 when viewed from above) is smaller than that of the barrier layer 4 made of Ti (the area of the barrier layer 4 when viewed from above).

Specifically, as illustrated in FIG. 4B, an about-0.5-μm-wide portion of Cu, more strictly the seed layer 5, is etched away by wet etching. Thus, recesses each having a depth of about 0.3 μm from a corresponding one of the side surfaces of the barrier layer 4 are each formed in the side surface of the seed layer 5. Specifically, the second wet etching of the seed layer 5 and the plated layer 6 both made of Cu provides a second interconnect 30 including the barrier layer 4 having a larger area when viewed from above than the seed layer 5. In this case, the area of the barrier layer 4 when viewed from above is slightly smaller than that of each of the Ni layer 7 and the Au layer 8 when viewed from above by the sum of the total area of portions of the plated layer 6 and the seed layer 5 etched away in lateral directions when viewed from above after the etching of the plated layer 6 and the seed layer 5 and the total area of portions of the barrier layer 4 etched away in lateral directions when viewed from above after the etching of the barrier layer 4 as illustrated in FIG. 4A. Specifically, recesses are formed after the etching of the plated layer 6 and the seed layer 5 and the etching of the barrier layer 4. The recesses each have a depth of about 0.5-1 μm from a corresponding one of the side surfaces of a combination of the Ni layer 7 and the Au layer 8.

Next, as illustrated in FIG. 4C, a protective film 9 made of SiN is formed on the second insulating film 3 by, e.g., CVD to cover the entire surfaces of the second interconnect 30 including upper and side surfaces thereof. Thereafter, an opening 9a is selectively formed in a portion of the protective film 9 immediately above the Au layer 8 by lithography and etching to enable connection of the second interconnect 30 to outside the semiconductor device. The opening 9a does not always need to be formed, depending on specifications.

The size of each of the components according to the first embodiment will be described hereinafter.

The aluminum film partially forming the first interconnects 2 has a thickness of about 1 μm, and the second insulating film 3 has a thickness of about 1-3 μm. The Ni layer 7 has a thickness of about 2-3 μm, and the Au layer 8 has a thickness of about 0.3-0.5 μm. The protective film 9 has a thickness of about 0.2-0.5 μm.

Portions of the second insulating film 3 immediately above the first interconnects 2 each have a thickness of about 0.5-1.0 μm.

Although not shown, the second interconnects 30 form a pattern including lines and spaces both having a minimum width of about 10 μm.

In the first embodiment, the barrier layer 4 made of Ti forms a portion of the second interconnect 30 serving as a redistribution interconnect, blocks the diffusion path for copper atoms between the barrier layer 4 and the first interconnects 2 below the barrier layer 4, and has a larger area when viewed from above than each of the seed layer 5 and the plated layer 6 both made of Cu. Thus, even when the electric field from the second interconnect 30 to the first interconnects 2 is at, e.g., about 5 MV/cm, the second interconnect 30 cannot be shorted to the first interconnects 2.

If the barrier layer 4 does not have a larger area when viewed from above than each of the seed layer 5 and the plated layer 6, i.e., if lower portions of the side surfaces of the second interconnect 30 partially protrude outward from the barrier layer 4 due to, for example, the etching of the barrier layer 4 in lateral directions, electrical shorting may be caused due to the diffusion of copper atoms even at an electric field of about 1 MV/cm.

The semiconductor device according to the first embodiment is, therefore, useful for, e.g., scan drivers, data drivers, devices for use in power supply, and motor-driving devices, which all require high voltage and low resistance.

### Second Embodiment

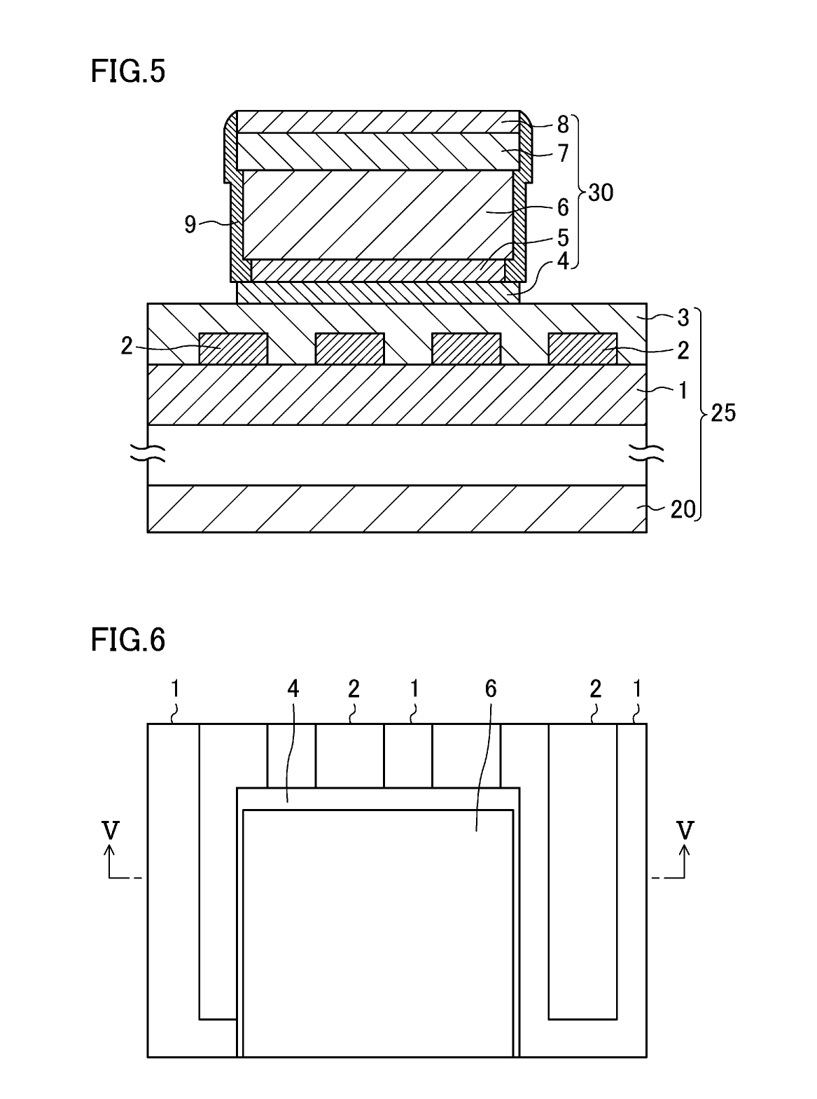

A semiconductor device according to a second embodiment of the present disclosure will be described hereinafter with reference to FIGS. 5 and 6. In FIG. 5, the same characters as those in FIG. 1 are used to represent equivalent components, and thus, the explanation thereof will be omitted.

As illustrated in FIG. 5, in the semiconductor device according to the second embodiment, a protective film 9 made of, e.g., SiN is formed in the form of a sidewall to cover side surfaces of a seed layer 5, a plated layer 6, a Ni layer 7, and an Au layer 8 that form a portion of a second interconnect 30, and a barrier layer 4 under the seed layer 5 is etched using the formed protective film 9 as an etching mask.

Thus, also in the second embodiment, the barrier layer 4 made of Ti, that is, a barrier film configured to prevent the diffusion of Cu, can easily and reliably have a larger area when viewed from above than each of the seed layer 5 and the plated layer 6 both containing Cu as the main ingredient, and consequently, Cu can be prevented from diffusing into lower interconnects.

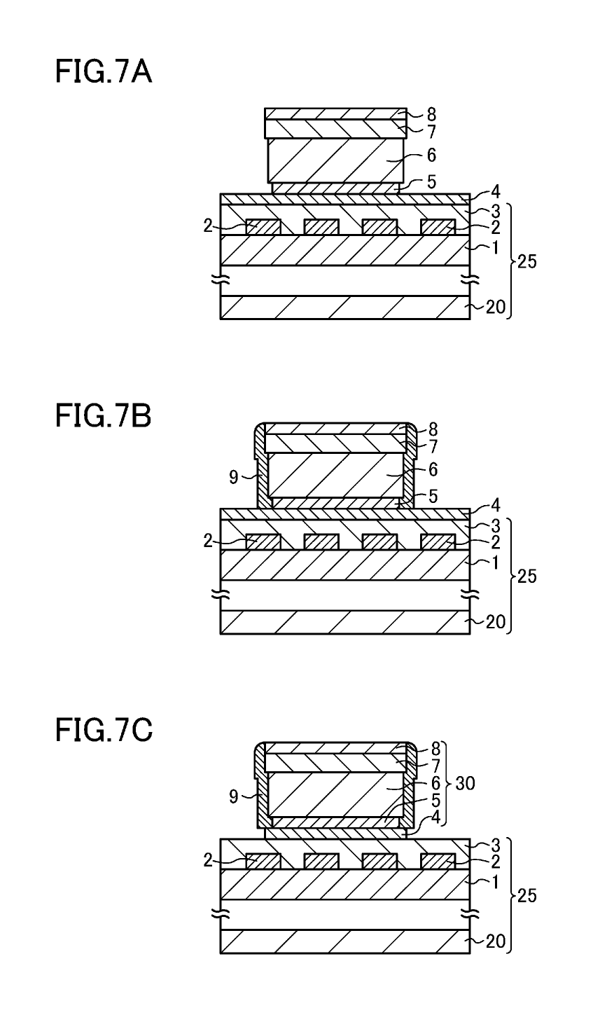

A method for fabricating the semiconductor device configured as above will be described hereinafter with reference to FIGS. 7A-7C. Process steps different from those in the first embodiment will be described here.

A process step illustrated in FIG. 7A is identical with the process step illustrated in FIG. 3D according to the method of the first embodiment. Specifically, FIG. 7A illustrates a situation where a seed layer 5 has been etched by wet etching using an etchant having a high etch rate for Cu.

Next, a protective film 9 made of SiN is formed on a barrier layer 4 by, e.g., CVD to cover all of side surfaces of the seed layer 5, a plated layer 6, and a Ni layer 7 and upper and side surfaces of an Au layer 8. Subsequently, the formed protective film 9 is etched back by dry etching. Thus, the protective film 9 is formed in the form of a sidewall to cover the side surfaces of the seed layer 5, the plated layer 6, the Ni layer 7, and the Au layer 8, thereby obtaining the state illustrated in FIG. 7B.

Next, as illustrated in FIG. 7C, the barrier layer 4 is etched using the protective film 9 formed in the form of the sidewall as a mask by wet etching with an etchant having a high etch rate for Ti. This allows the formation of a second interconnect 30 having a lower portion including the barrier layer 4.

The barrier layer 4 made of Ti has a thickness of about 0.2 μm, and the side surfaces of the barrier layer 4 each have a recess having a depth of about 0.2 μm from a corresponding one of the side surfaces of the protective film 9, i.e., a recess having a depth substantially equal to the thickness of the barrier layer 4.

Also in the second embodiment, for example, the thicknesses of components are equivalent to those in the first embodiment. The thickness of a portion of the protective film 9 on each of the side surfaces of the plated layer 6 is about 0.2-0.5 μm.

As such, according to the second embodiment, when a recess having a depth of about 0.2 μm is formed in each of both the side surfaces of the barrier layer 4, the thickness of a portion of the protective film 9 on the side surface of the plated layer 6 is greater than the depth of the recess. This allows the barrier layer 4 made of Ti to have a larger area when viewed from above than each of the seed layer 5 and the plated layer 6 both made of Cu, and the barrier layer 4, therefore, blocks the diffusion path of Cu into the first interconnects 2. Thus, even when the electric field from the second interconnect 30 to the first interconnects 2 that are lower interconnects is at, e.g., about 5 MV/cm, the second interconnect 30 cannot be shorted to the first interconnects 2.

Although not shown, a new protective film 9 made of SiN may be formed on the second insulating film 3 to cover the entire surfaces of the second interconnect 30 including upper and side surfaces thereof after the process step in FIG. 7C similarly to the process step in FIG. 4C. Furthermore, an opening 9a may be selectively formed in a portion of the new protective film 9 immediately above the Au layer 8.

### Third Embodiment

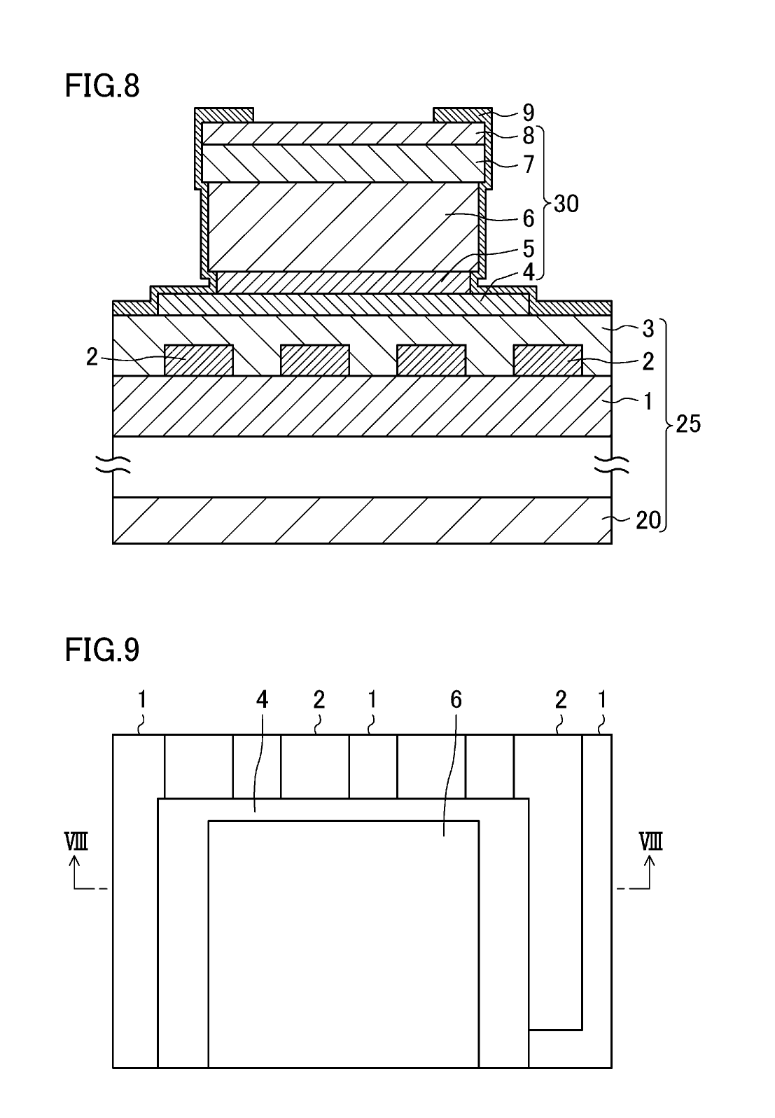

A semiconductor device according to a third embodiment of the present disclosure will be described with reference to FIGS. 8 and 9. In FIG. 8, the same characters as those in FIG. 1 are used to represent equivalent components, and thus, the explanation thereof will be omitted.

As illustrated in FIG. 8, in the semiconductor device according to the third embodiment, instead of a protective film 9 formed in the form of a sidewall and used as an etching mask in the second embodiment, a sufficiently thick resist mask is used to etch a barrier layer 4.

In the third embodiment, the use of the sufficiently thick resist mask ensures that the barrier layer 4 made of Ti and corresponding to a barrier film configured to prevent the diffusion of Cu has a larger area when viewed from above than each of the seed layer 5 and the plated layer 6 both containing Cu as the main ingredient. This can further ensure that Cu is prevented from diffusing into lower interconnects.

(First Fabrication Method)

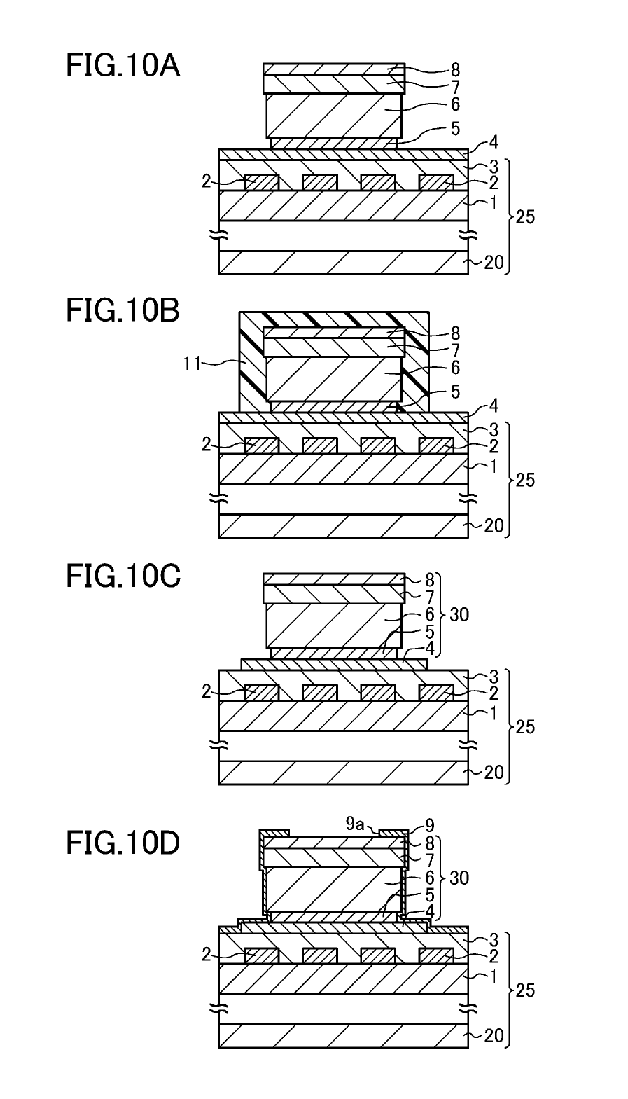

A first method for fabricating a semiconductor device according to the third embodiment will be described hereinafter with reference to FIGS. 10A-10D. Process steps different from those in the second embodiment will be described.

A process step illustrated in FIG. 10A is identical with the process step illustrated in FIG. 7D according to the method of the second embodiment. Specifically, FIG. 10A illustrates a situation where a seed layer 5 has been etched by wet etching using an etchant having a high etch rate for Cu.

Next, as illustrated in FIG. 10B, a resist film 11 is formed on a barrier layer 4 by lithography to cover all of side surfaces of the seed layer 5, a plated layer 6, and a Ni layer 7 and upper and side surfaces of an Au layer 8.

Next, as illustrated in 10C, the barrier layer 4 is etched using the resist film 11 as a mask by wet etching with an etchant having a high etch rate for Ti. This allows the formation of a second interconnect 30 having a lower portion including the barrier layer 4. Here, instead of wet etching, dry etching can be used. Then, the resist film 11 is removed.

As such, according to the first fabrication method of the third embodiment, the width of each of portions of the barrier layer 4 laterally protruding beyond both side surfaces of the plated layer 6 can be adjusted depending on the thickness of the resist film 11. This can ensure that the barrier layer 4 made of Ti has a larger area when viewed from above than each of the seed layer 5 and the plated layer 6 both made of Cu. Furthermore, since the resist film 11 formed by lithography is used as a mask, the fabrication accuracy can be increased.

However, as described above, a plurality of second interconnects 30 are formed in parallel, and for this reason, if the distance (space) between each adjacent pair of the second interconnects 30 is small, this may increase the aspect ratio of the space formed by etching using the resist film 11, and thus, may make it difficult to pattern a bottom portion of the second interconnect 30. Thus, in this embodiment, in consideration of a margin, the thickness of a portion of the resist film 11 on each of the side surfaces of the plated layer 6, i.e., the width of each of portions of the barrier layer 4 laterally protruding beyond the side surfaces of the plated layer 6, is about 1-2 μm. The width of each of portions of the barrier layer 4 laterally protruding beyond the side surfaces of the plated layer 6 is not limited to the value, and may be appropriately determined depending on the distance (space) between each adjacent pair of the second interconnects 30 and the height of each of the second interconnects 30.

Thereafter, as illustrated in FIG. 10D, a protective film 9 made of SiN is formed on a second insulating film 3 to cover the entire surfaces of the second interconnect 30 including upper and side surfaces thereof. Subsequently, an opening 9a is selectively formed in a portion of the formed protective film 9 immediately above the Au layer 8.

As such, the second interconnect 30 of the semiconductor device according to the third embodiment includes the barrier layer 4 having a larger area when viewed from above than the plated layer 6 and further having a larger area when viewed from above than each of the Ni layer 7 and the Au layer 8. The protective film 9 also covers side surfaces of the barrier layer 4.

(Second Fabrication Method)

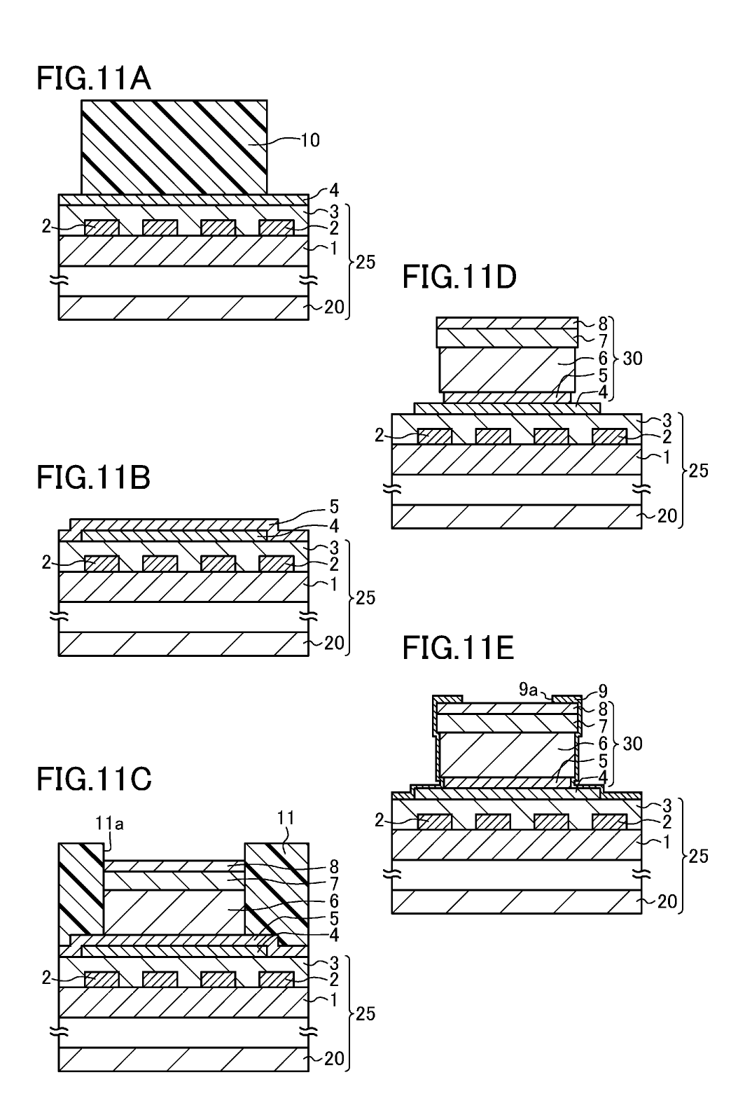

A second method for fabricating a semiconductor device according to the third embodiment will be described with reference to FIGS. 11A-11E. In the second fabrication method, a barrier layer 4 made of Ti and formed on a second insulating film 3 is patterned, and then, a seed layer 5 made of Cu is deposited.

Specifically, as illustrated in FIG. 11A, a resist film 10 used to pattern the barrier layer 4 is formed, by lithography, on the barrier layer 4 deposited by sputtering.

Next, as illustrated in FIG. 11B, the barrier layer 4 is etched using the formed resist film 10 as a mask, and then, the resist film 10 is removed. Subsequently, a seed layer 5 made of Cu is deposited on the entire surface of the third insulating film 3 by sputtering to cover the patterned barrier layer 4. Before the deposition of the seed layer 5, a cleaning process, for example, is performed to clean the surface of the barrier layer 4.

Next, as illustrated in FIG. 11C, a resist film 11 is formed by lithography, and has an opening pattern 11a in its region where a second interconnect is to be formed. Here, the opening pattern 11a of the resist film 11 is above the seed layer 5, and has a smaller width than the patterned barrier layer 4. Subsequently, a plated layer 6 made of Cu is grown on the seed layer 5 by electroplating using the resist film 11 as a mask. Subsequently, a Ni layer 7 and an Au layer 8 are sequentially grown on the plated layer 6 by electroplating.

Next, as illustrated in FIG. 11D, the resist film 11 is removed, and then, the seed layer 5 is etched by wet etching with an etchant having a high etch rate for Cu. Also here, the seed layer 5 made of Cu has a thickness of about 0.2 μm, and a recess having a depth substantially equal to the thickness of the seed layer 5 is formed in each of side surfaces of the seed layer 5. In other words, the etching of the seed layer 5 proceeds in lateral directions.

Next, as illustrated in FIG. 11E, a protective film 9 made of SiN is formed on the second insulating film 3 by, e.g., CVD to cover the entire surfaces of the second interconnect 30 including upper and side surfaces thereof. Thereafter, an opening 9a is selectively formed in a portion of the protective film 9 immediately above the Au layer 8 by lithography and etching to enable connection of the second interconnect 30 to outside the semiconductor device. As described above, the opening 9a does not always need to be formed.

Similarly to the first fabrication method, in consideration of a margin, the thickness of a portion of the resist film 11 on each of the side surfaces of the barrier layer 4, i.e., the width of each of portions of the barrier layer 4 laterally protruding beyond the side surfaces of the plated layer 6, is about 1-2 μm.

As such, the second interconnect 30 of the semiconductor device according to the third embodiment includes the barrier layer 4 having a larger area when viewed from above than the plated layer 6 and further having a larger area when viewed from above than each of the Ni layer 7 and the Au layer 8. The protective film 9 also covers the side surfaces of the barrier layer 4.

### Fourth Embodiment

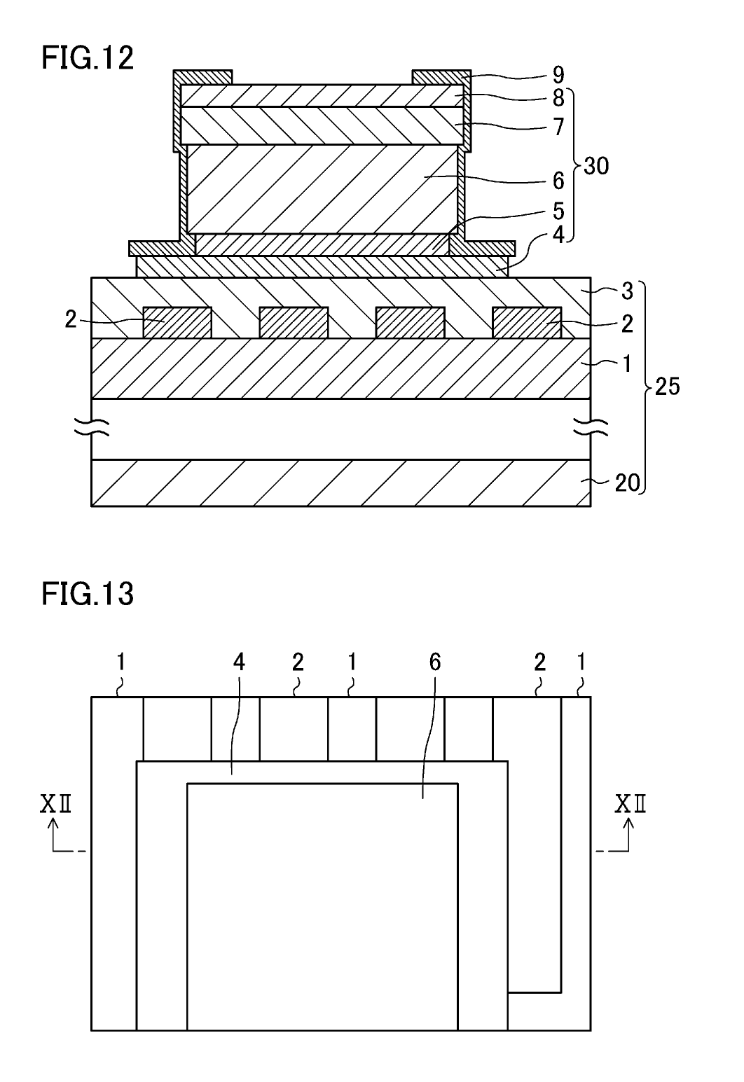

A semiconductor device according to a fourth embodiment of the present disclosure will be described with reference to FIGS. 12 and 13. In FIG. 12, the same characters as those in FIG. 1 are used to represent equivalent components, and thus, the explanation thereof will be omitted.

As illustrated in FIG. 12, the semiconductor device according to the fourth embodiment includes a barrier layer 4 made of Ti. The barrier layer 4 is formed using, as a mask, a protective film patterned with a sufficiently thick resist mask.

Also in the fourth embodiment, such formation of the barrier layer 4 ensures that the barrier layer 4 made of Ti and corresponding to a barrier film configured to prevent the diffusion of Cu has a larger area when viewed from above than each of the seed layer 5 and the plated layer 6 both containing Cu as the main ingredient. This can further ensure that Cu is prevented from diffusing into lower interconnects.

(First Fabrication Method)

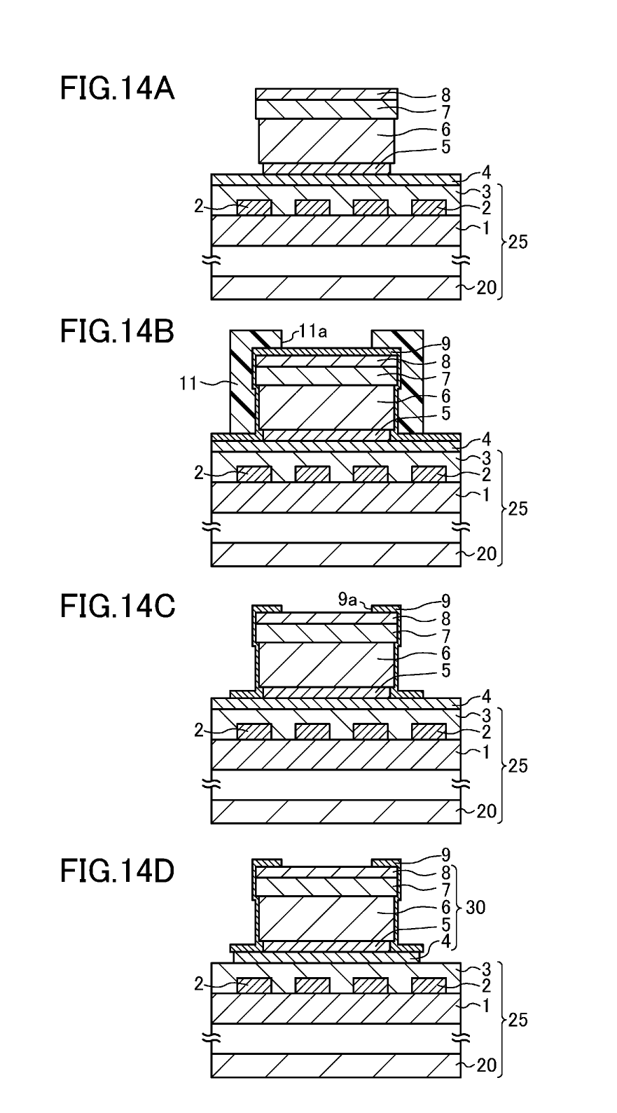

A first method for fabricating a semiconductor device according to the fourth embodiment will be described with reference to FIGS. 14A-14D. In the first fabrication method, a protective film 9 is used as a mask for patterning a barrier layer 4. Furthermore, a resist film used to pattern the protective film 9 is used also to form an opening 9a in the protective film 9.

A process step illustrated in FIG. 14A is identical with the process step illustrated in FIG. 3D according to the method of the first embodiment. Specifically, FIG. 14A illustrates a situation where a seed layer 5 has been etched by wet etching with an etchant having a high etch rate for Cu.

Next, as illustrated in FIG. 14B, a protective film 9 made of SiN is formed on the barrier layer 4 by, e.g., CVD to cover all of side surfaces of the seed layer 5, a plated layer 6, and a Ni layer 7 and upper and side surfaces of an Au layer 8. Subsequently, a resist film 11 is formed on the protective film 9 by lithography to cover the side surfaces of the seed layer 5, the plated layer 6, and the Ni layer 7 and the upper and side surfaces of the Au layer 8. In this case, an opening pattern 11a through which the protective film 9 is to be electrically connected to outside the semiconductor device is formed in a region of the resist film 11 immediately above the Au layer 8.

Next, as illustrated in FIG. 14C, the protective film 9 is patterned by etching the protective film 9 using the resist film 11 as a mask, and an opening 9a is formed. Here, dry etching with a gas mixture containing fluorocarbon as the main ingredient can be used to etch the protective film 9.

Next, as illustrated in FIG. 14D, the barrier layer 4 is etched using the protective film 9 as a mask by wet etching with an etchant having a high etch rate for Ti. This allows the formation of a second interconnect 30 having a lower portion including the barrier layer 4. In this case, the barrier layer 4 made of Ti has a thickness of about 0.2 μm, and therefore, the side surfaces of the barrier layer 4 each have a recess having a depth of about 0.2 μm from a corresponding one of the side surfaces of the protective film 9, i.e., a recess having a depth substantially equal to the thickness of the barrier layer 4.

As such, the second interconnect 30 of the semiconductor device according to the fourth embodiment includes the barrier layer 4 having a larger area when viewed from above than the plated layer 6 and further having a larger area when viewed from above than each of the Ni layer 7 and the Au layer 8. The protective film 9 does not cover the side surfaces of the barrier layer 4.

Furthermore, since the protective film 9 is formed before the patterning of the barrier layer 4, and the barrier layer 4 is patterned using the patterned protective film 9, this can reduce the number of lithography process steps.

Also in this embodiment, the width of each of portions of the barrier layer 4 laterally protruding beyond the side surfaces of the plated layer 6 is about 1-2 μm.

(Second Fabrication Method)

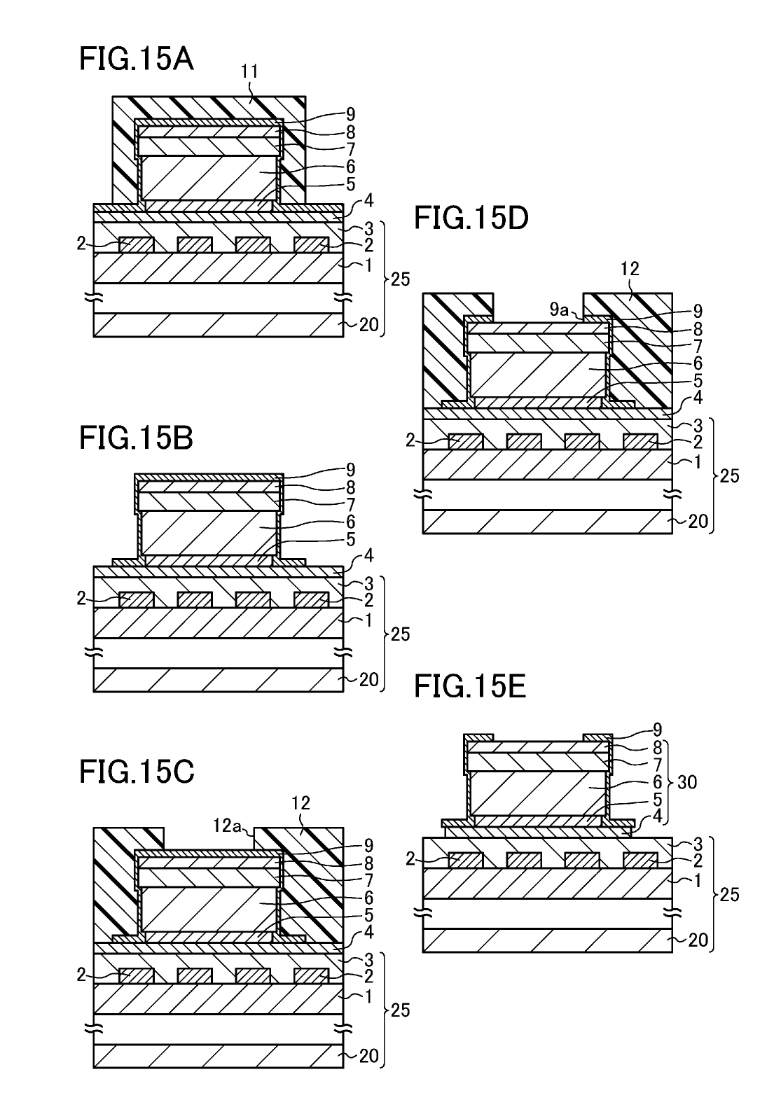

A second method for fabricating a semiconductor device according to the fourth embodiment will be described with reference to FIGS. 15A-15E. In the second fabrication method, a protective film 9 formed above a second insulating film 3 is patterned using a resist film 11, and then, the protective film 9 is patterned using a resist film 12 to form an opening 9a in the protective film 9. Specifically, the resist film 11 is used to pattern the protective film 9, and the resist film 12 is used to form the opening 9a of the protective film 9.

FIG. 15A illustrates a situation where the protective film 9 and the resist film 11 have been formed after the process step illustrated in FIG. 14B according to the first fabrication method.

Specifically, the protective film 9 made of SiN is formed on a barrier layer 4 by, e.g., CVD to cover all of side surfaces of a seed layer 5, a plated layer 6, and a Ni layer 7 and upper and side surfaces of an Au layer 8. Subsequently, the resist film 11 is formed on the protective film 9 by lithography to cover the side surfaces of the seed layer 5, the plated layer 6, and the Ni layer 7 and the upper and side surfaces of the Au layer 8. Also here, the thickness of a portion of the resist film 11 on each of the side surfaces of the plated layer 6 is about 1-2 μm.

Next, the protective film 9 is etched using the resist film 11 as a mask to pattern the protective film 9. Thereafter, the resist film 11 is removed to obtain the state illustrated in FIG. 15B.

Next, as illustrated in FIG. 15C, the resist film 12 having an opening pattern 12a above a region of the protective film 9 on the Au layer 8 is formed by lithography.

Next, as illustrated in FIG. 15D, the protective film 9 is etched using the resist film 12 as a mask to form the opening 9a in the protective film 9. Thereafter, the resist film 12 is removed.

Next, as illustrated in FIG. 15E, the barrier layer 4 is etched using the protective film 9 as a mask by wet etching with an etchant having a high etch rate for Ti. This allows the formation of a second interconnect 30 having a lower portion including the bather layer 4. In this case, the barrier layer 4 made of Ti has a thickness of about 0.2 μm, and therefore, the side surfaces of the barrier layer 4 each have a recess having a depth of about 0.2 μm from a corresponding one of the side surfaces of the protective film 9, i.e., a recess having a depth substantially equal to the thickness of the barrier layer 4.

As such, the second interconnect 30 of the semiconductor device according to the fourth embodiment includes the barrier layer 4 having a larger area when viewed from above than the plated layer 6 and further having a larger area when viewed from above than each of the Ni layer 7 and the Au layer 8. The protective film 9 does not cover the side surfaces of the barrier layer 4.

The barrier layer 4 may be etched after the process step illustrated in FIG. 15B instead of in the last process step illustrated in FIG. 15E.

In the fourth embodiment, unlike the first fabrication method, in the second fabrication method, two resist films are used to etch the protective film 9. Among the two resist films, the resist film 11 is used to obtain a mask for the barrier layer 4, and the resist film 12 is used to obtain the opening 9a.

As such, although, in the second fabrication method, the number of lithography process steps and the number of etching process steps increase, exposure light can be focused on a portion of the resist film 11 over the barrier layer 4. Furthermore, exposure light can be focused on a portion of the resist film 12 above the Au layer 8. This can improve the accuracy of patterning.

### Fifth Embodiment

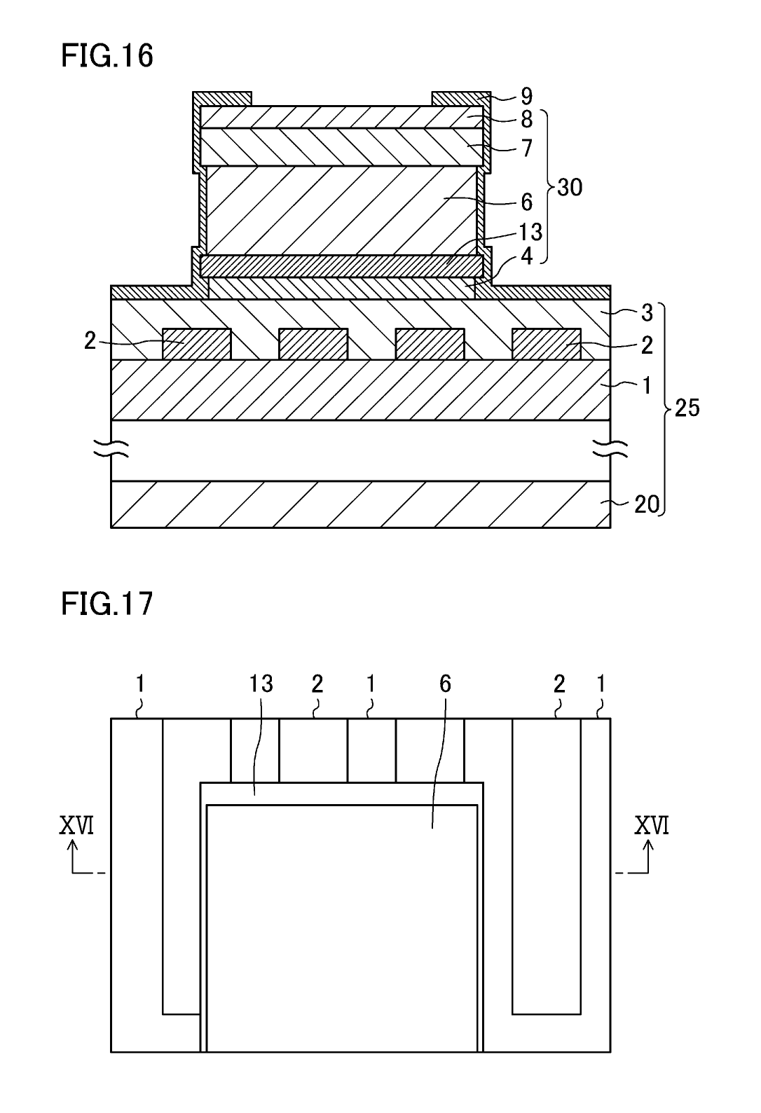

A semiconductor device according to a fifth embodiment of the present disclosure will be described hereinafter with reference to FIGS. 16 and 17. In FIG. 16, the same characters as those in FIG. 1 are used to represent equivalent components, and thus, the explanation thereof will be omitted.

As illustrated in FIG. 16, in the semiconductor device according to the fifth embodiment, instead of a seed layer 5 made of Cu and formed on a barrier layer 4 made of Ti, a barrier layer 13 made of a metal serving as a barrier against Cu, such as nickel (Ni), is used.

Also in the fifth embodiment, the barrier layer 4 made of Ti and serving as a barrier film configured to prevent diffusion of copper and the barrier layer 13 made of Ni each have a larger area when viewed from above than a plated layer 6 containing copper as the main ingredient, and thus, prevent diffusion of copper into lower interconnects.

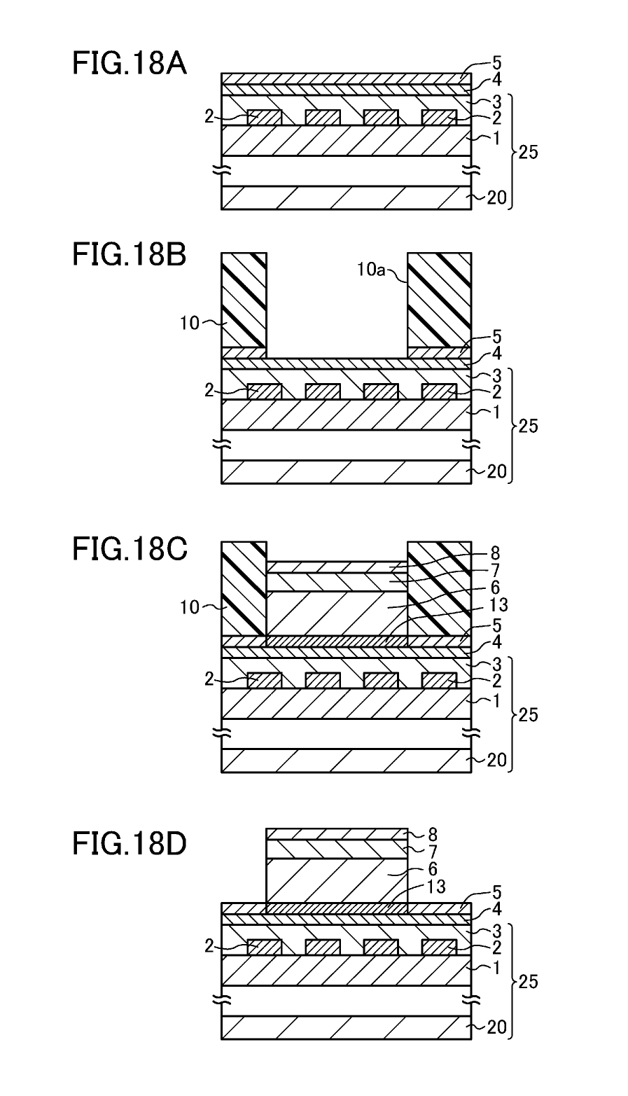

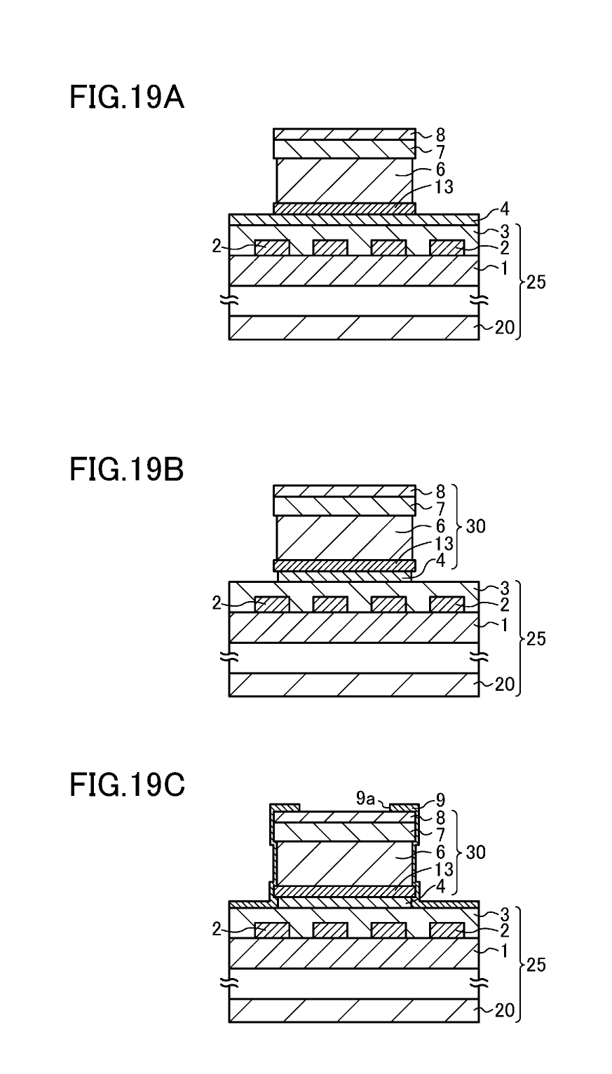

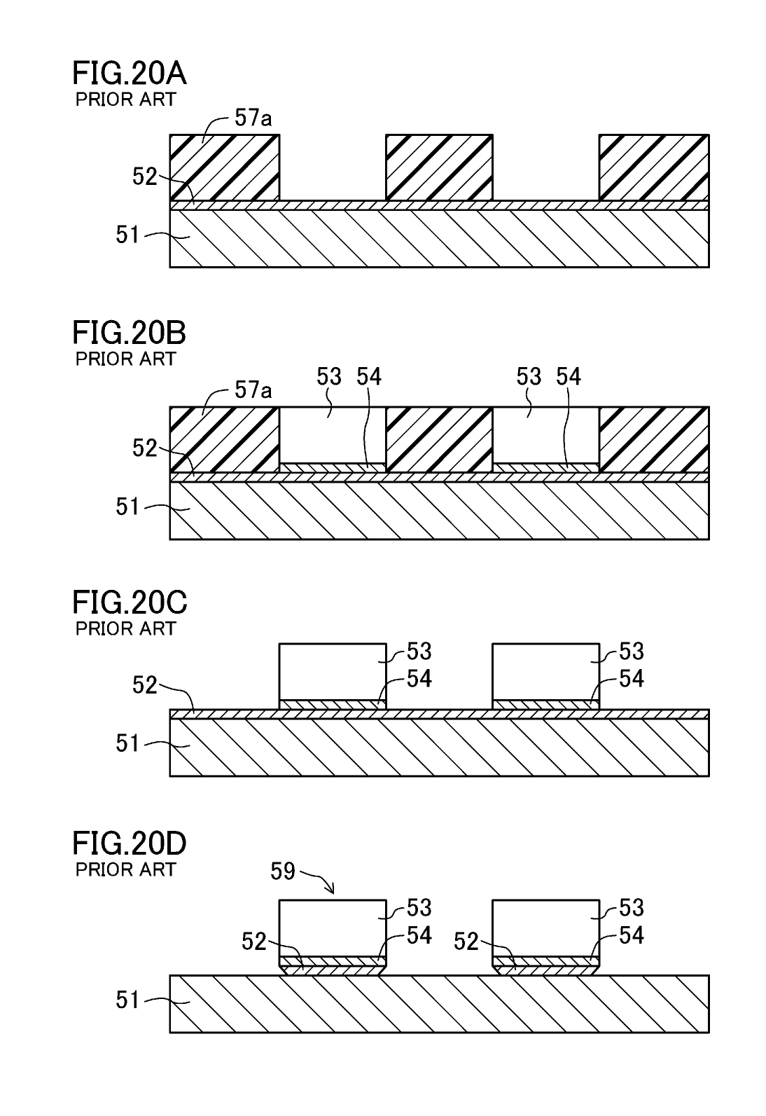

A method for fabricating the semiconductor device configured as above will be described with reference to FIGS. 18A-19C.

First, as illustrated in FIG. 18A, a first insulating film 1 is formed, by, e.g., CVD, on a semiconductor substrate 20 on which an active element, interconnect layers, and other elements are formed. Subsequently, an interconnect formation film made of Al is deposited on the first insulating film 1 by sputtering. Thereafter, the interconnect formation film is patterned to form a plurality of first interconnects 2. Subsequently, a second insulating film 3 is deposited on the first insulating film 1 to cover the first interconnects 2. Subsequently, a barrier layer 4 made of Ti and a seed layer 5 made of Cu are sequentially deposited on the second insulating film 3 by sputtering.

Next, as illustrated in FIG. 18B, a resist film 10 is formed on the seed layer 5 by lithography, and has an opening pattern 10a in its region in which a second interconnect is to be formed, and the seed layer 5 is patterned using the formed resist film 10 as a mask. In this case, the seed layer 5 is etched by wet etching.

Next, as illustrated in FIG. 18C, a barrier layer 13 made of Ni and a plated layer 6 made of Cu are sequentially grown on the barrier layer 4 by electroplating using the resist film 10 as a mask. Subsequently, a Ni layer 7 and an Au layer 8 are sequentially grown on the plated layer 6 by electroplating.

Next, as illustrated in FIG. 18D, the resist film 10 is removed.

Next, as illustrated in FIG. 19A, the seed layer 5 made of Cu and remaining to surround the bather layer 13 made of Ni is removed using an etchant having a high etch rate for Cu. In this case, since the barrier layer 13 made of Ni is hardly etched, side surfaces of the barrier layer 13 are each located outward of a corresponding one of side surfaces of the plated layer 6, and the barrier layer 13 is not etched in lateral directions.

Next, as illustrated in FIG. 19B, the barrier layer 4 made of Ti is etched using the barrier layer 13 made of Ni as a mask by wet etching with an etchant having a high etch rate for Ti. This provides a second interconnect 30 including the barrier layer 13 having a larger area when viewed from above than the plated layer 6. In this case, the area of the barrier layer 13 when viewed from above is substantially equivalent to that of each of the Ni layer 7 and the Au layer 8 when viewed from above. Here, the side surfaces of the barrier layer 4 each have a recess having a depth of about 0.2 μm from a corresponding one of the side surfaces of the barrier layer 13, i.e., a depth substantially equal to the thickness of the barrier layer 4.

Next, as illustrated in FIG. 19C, a protective film 9 made of SiN is formed on the second insulating film 3 by, e.g., CVD to cover the entire surfaces of the second interconnect 30 including upper and side surfaces thereof. Thereafter, an opening 9a is selectively formed in a portion of the protective film 9 immediately above the Au layer 8 by lithography and etching to enable connection of the second interconnect 30 to outside the semiconductor device.

In the fifth embodiment, the barrier layer 13 made of Ni forms a portion of the second interconnect 30 serving as a redistribution interconnect, blocks the diffusion path for copper atoms between the barrier layer 13 and the first interconnects 2 below the barrier layer 13, and has a larger area when viewed from above than the plated layer 6 made of Cu. Thus, even when the electric field from the second interconnect 30 to the first interconnects 2 is at, e.g., about 5 MV/cm, the second interconnect 30 cannot be shorted to the first interconnects 2.

As such, according to the fifth embodiment, even if the etching of the barrier layer 4 made of Ti proceeds in lateral directions, the barrier layer 13 made of Ni is formed on the barrier layer 4 so as not to be etched in lateral directions, thereby ensuring that the diffusion of Cu is prevented.

The semiconductor device according to the present disclosure and the method for fabricating the same according to the present disclosure can reduce, for example, the leakage current between lower interconnects and a relatively thick upper interconnect, can prevent the upper interconnect from being shorted to the lower interconnects, and thus, are useful, in particular, for, for example, a semiconductor device including a redistribution layer formed on a semiconductor chip.

What is claimed is:

1. A semiconductor device comprising:
a first insulating film formed on a semiconductor substrate;
a first interconnect formed on the first insulating film;
a second insulating film formed on the first insulating film to cover the first interconnect;
a second interconnect formed on the second insulating film; and
an insulative protective film formed on an upper surface or a side surface of the second interconnect, wherein
the second interconnect includes a first barrier layer formed on the second insulating film, and a first conductive layer formed above the first barrier layer,
a width of the first barrier layer is greater than a width of the first conductive layer, and
a thickness of the insulative protective film is less than a thickness of the first conductive layer.

2. The semiconductor device of claim 1 further comprising:
a conductive film located between the semiconductor substrate and the first conductive layer and above or below the first barrier layer, wherein
a lateral end surface of the conductive film is located inward from a lateral end surface of an upper film formed in contact with an upper surface of the conductive film.

3. The semiconductor device of claim 2, wherein
the conductive film is a seed layer formed between the first barrier layer and the first conductive layer, and the upper film is the first conductive layer.

4. The semiconductor device of claim 2, wherein
the conductive film is a second barrier layer formed between the first barrier layer and the semiconductor substrate, and the upper film is the first barrier layer.

5. The semiconductor device of claim 1, wherein
the insulative protective film is formed in contact with the side surface of the second interconnect, and
the insulative protective film is formed without covering a side surface of the first barrier layer.

6. The semiconductor device of claim 1, wherein
the second interconnect further includes a second conductive layer formed on the first conductive layer and including at least one layer.

7. The semiconductor device of claim 6, wherein
in the second interconnect, the width of the first barrier layer is greater than a width of the second conductive layer, and the width of the second conductive layer is greater than the width of the first conductive layer.

8. The semiconductor device of claim 6, wherein
a width of the second conductive layer of the second interconnect is greater than the width of the first barrier layer.

9. The semiconductor device of claim 6, wherein
the second conductive layer contains nickel or gold.

10. The semiconductor device of claim 1, wherein
the insulative protective film covers a side surface of the first barrier layer.

11. The semiconductor device of claim 1, wherein
the first conductive layer of the second interconnect is made of a material containing copper.

12. The semiconductor device of claim 1, wherein
the insulative protective film has an opening through which the upper surface of the second interconnect is exposed.
